(19) United States
(12) Patent Application Publication
(10) Pub. No.: US 2018/0041854 A1
(43) Pub. Date: Feb. 8, 2018

(54) DEVICE FOR CREATION OF OBJECT DEPENDENT AUDIO DATA AND METHOD FOR CREATING OBJECT DEPENDENT AUDIO DATA IN A VEHICLE INTERIOR

(71) Applicants: Axel Torschmied, Erftstdt (DE); Alexander Van Laack, Aachen (DE)

(72) Inventors: Axel Torschmied, Erftstdt (DE); Alexander Van Laack, Aachen (DE)

(21) Appl. No.: 15/669,511

(22) Filed: Aug. 4, 2017

(30) Foreign Application Priority Data
Aug. 4, 2016 (DE) 10 2016 114 413.4

(51) Int. Cl. H04S 7/00; H04S 3/00; H04R 5/04; H03G 5/16; G08G 1/16; H04R 5/02

(52) U.S. Cl. CPC H04S 7/303; G08G 1/166; H04R 5/02; H04R 5/04; H03G 5/165; H04S 3/008; H04R 2499/13; H04S 2400/11; H04S 2400/01

(57) ABSTRACT

The disclosure relates to a device to create object dependent audio data including a plurality of driver assistance systems and their sensors, a database with audio data, an object based audio manager, a renderer, and a plurality of loudspeakers, whereby the plurality of driver assistance systems and/or their sensors exchange data with the object based audio manager, whereby the object based audio manager exchanges data with the renderer and whereby the renderer is connected to the loudspeakers.

### CROSS-REFERENCE TO RELATED APPLICATION

This application claims priority to German Patent Application No. 10 2016 114 413.4 filed Aug. 4, 2016 and entitled “Device for creation of object dependent audio data and method for creating object dependent audio data in a vehicle interior,” which is herein incorporated by reference.

### BACKGROUND

Modern vehicles have a plurality of Advance Driver Assistance Systems (ADAS) and sensors that help a driver when driving and warn him of dangers. Since practically all ADAS items of information are presented visually, the visual channel is overloaded with separate items. The flood of information detracts from the driver's concentration, since the large number of screens and warning lights distract the driver from observing events around the vehicle.

Till now sounds have been used only sparingly to inform the driver about hazardous situations. Thus a system is known from DE 10 2014 221 301 A1 in which an audio panorama with microphones is recorded and displayed to a user as an indicator of the presence of hazards or other events of interest.

### SUMMARY

This disclosure relates to acoustically sending information to the driver of a vehicle without additional sensors in the vehicle about moving and static objects around the vehicle or other warnings.

This disclosure relates to a device, also called an acoustic man-machine interface (MMI) to create object dependent audio data, including a plurality of driver assistance systems and their sensors, a database with audio data, an object based audio manager, a renderer (multi-channel sound system), and a plurality of loudspeakers, whereby the plurality of driver assistance systems and/or their sensors exchange data with the database and the object based audio manager, whereby the object based audio manager exchanges data with a renderer and whereby the renderer is connected to the loudspeakers.

The advantage of this device is that already existing driver assistance systems and their sensors are accessed, so that as a result the installation of other sensors is not necessary. Already existing sensor data/ADAS information in the vehicle can thus be used to create object based audio output.

Thereby every detected object can be created as a spatial sound the object, based on the use of object based audio technology.

Hereby an “object based audio” is used in order to allow the user to have a targeted perception of the audio signals.

In order to utilize the full potential, the audio-based system should be networked within the vehicle as well as possible with other devices, with access to all vehicle and sensor modules, in order to receive the information necessary for the creation of a broadened reality.

The device presents an object based audio system that serves to record the surroundings via sensors and to emit them with correct direction and space intervals into the interior of the vehicle.

The plurality of auto assistance systems and/or their sensors, the database, and the object based audio manager preferentially exchange data with an effect device and an equalizer.

The driver assistance systems and their sensors are preferentially selected from the group including V2X Communications Systems, such as vehicle to vehicle communications systems (V2V Communications Systems) and vehicle infrastructure Communications Systems (V2I Communications Systems), distance sensors, microphones, communications systems ((e.g., mobile broadcasting systems and wireless communication systems) for communication among several vehicles, position determination systems, location determination systems, such as GPS, (video) camera systems, ultrasound systems, laser rangefinder systems, radar systems, and navigation systems.

The sensors are preferentially set up in or on a vehicle, so that they cover the entire vehicle or at least the part of the surrounding area that is relevant to the driver.

In one preferred embodiment, the loudspeakers are set up in the interior of a vehicle.

The object based sounds that can be emitted by the plurality of loudspeakers are preferentially created on the basis of a wave field synthesis.

In another preferred embodiment, the loudspeakers are set up in the headrests of a vehicle.

The object based sounds that can be emitted by the loudspeakers in the headrests of a vehicle seat are preferentially able to be created binaurally.

One embodiment, in which the loudspeakers are set up in the headrests of a vehicle seat, allows sending the object based audio signals (sounds) to a specific person or to a specific group among the occupants, while among other setup possibilities, the loudspeakers, such as through a plurality of loudspeakers that are set up in the interior of a vehicle, such as in the interior lining of the vehicle or the vehicle roof, and the object based audio signals are so emitted that all occupants can hear them. One algorithm in the audio generator determines whether the information and/or warnings that are emitted are sent to only a limited group of people or only to one person in the vehicle interior.

The renderer is preferentially an object based audio system that creates wave fields, so that a spatial sound impression is created for the driver and/or other occupantss in the vehicle interior. The object-oriented audio output that is received in this way contains information about the position of an object and its speed and direction or about operating conditions of the vehicle. According to the type of the object, however, other information may also be emitted about the object. The objects may thereby be created dynamically between the loudspeakers. This occurs through a plurality of loudspeakers that are set up at various positions in the vehicle interior.

In addition, the task is solved by a method of the type noted in the introduction, in which information and warning signals that come from the driver assistance systems and/or their sensors are processed by an audio generator through exchange with a data base with audio data into object based sounds (tones), and then these are further emitted in the interior of the vehicle by loudspeakers that are set up through superposition of the signals (summary signals).

One algorithm creates the sound objects during the running time and settles these within or outside the vehicle, depending on the present case of application of sound augmentation. In order to achieve most optimal sound augmentation, wave fields syntheses or binaural algorithms are used.

Thereby sounds (tones/acoustic signals) and noises are so emitted that the driver has the feeling that they are actually coming from an object (e.g., from another participant in traffic). Thereby the wave fronts given off from the position of the object based sounds (tones) in the space are calculated, and are correspondingly sent via loudspeakers into the interior of the vehicle. Hereby actual and artificial (or real) sounds (tones) are overlaid with the position and speed of other objects. The position of a hazard outside the vehicle is determined, and the sound (tone) set exactly on this position so that for the driver and all the other occupants it would seem that the sound comes exactly from this object.

Thereby internal systems are accessed that communicate the position of obstacles or other participants in traffic and give these as accurate space response in the vehicle interior.

Accordingly, sounds are acoustical signals in the form of tones, noises, voices, etc.

Information and warning signals that come from driver assistance systems and/or their sensors are preferentially processed into object based sounds by an effect device and an equalizer that exchange audio data with the database, which are sent on to the object based audio manager.

The information and warning signals preferentially include position data of the vehicle or another vehicle, navigation data, information about traffic signs, traffic warning signals, local services, trace information, services connected with the vehicle, vehicle information, service information, distance data to other movable or stationary objects, information about other vehicles within a selected group of vehicles, and verbal information of the driver within the selected group of vehicles.

Additionally, a sound modulation based on vehicle parameters is conceivable in this connection—for example, to warn the driver that refueling must be done, that there are defects, that the tire pressure is not optimal, or that there are other problems with the vehicle.

The information and warning signals are preferentially emitted via a renderer in the interior of the vehicle (preferentially a multi channel tone system), which has a plurality of loudspeakers, so that as a result an object related audio emission occurs that contains information about the position of the object and its speed and direction.

In a preferred embodiment, the object based sounds that are emitted by the plurality of loudspeakers are created on the basis of wave field synthesis. For this, a number of loudspeakers are set up in the vehicle interior, for example, in the vehicle inner furnishing or the vehicle roof

In another preferred embodiment, the object based sounds are emitted binaurally through loudspeakers in the headrests of a vehicle seat.

### BRIEF DESCRIPTION OF THE DRAWINGS

Other individual items, characteristics, and advantages of embodiments of the invention result from the following description of examples with reference to the relevant figures. In particular there is shown:

FIG. 1 a flow diagram of the method to create object dependent audio data of a vehicle

FIG. 2 a schematic presentation of the positions of objects and their movement outside a vehicle with relation to the vehicle,

FIG. 3 a schematic presentation of the positions of objects and their movement outside a vehicle in relation to the driver of a vehicle or the occupants.

FIG. 4 a schematic presentation of a vehicle with loudspeakers,

FIG. 5 a schematic presentation of the setup of loudspeakers on a vehicle seat, and

FIG. 6 a schematic presentation of a device to create object dependent audio data.

### DETAILED DESCRIPTION

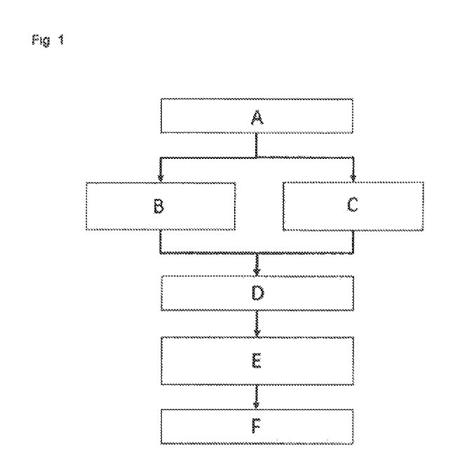

FIG. 1 shows a flow diagram of the method for creating object dependent audio data in a vehicle 1, in which initially data already present in the vehicle assistance system of the vehicle 1 are accessed, or the surrounding area of the vehicle 1 is detected and identified (A) by the sensors 2. Spatial information, such as position, speed, and direction are communicated (B). In addition, surrounding items of field information, such as the type of object, sound (of the object), are communicated (C). Then virtual sound objects in an audio MMI creator (D) are created from the data communicated in steps B and C, and these virtual sound objects are created/rendered in relation to the real object (position and surround location) (E). The audio instructions so obtained are played out in the vehicle interior through a plurality of loudspeakers, through wave field synthesis, or binaurally with loudspeakers on the headrests 12 of the driver's seat 3 (F).

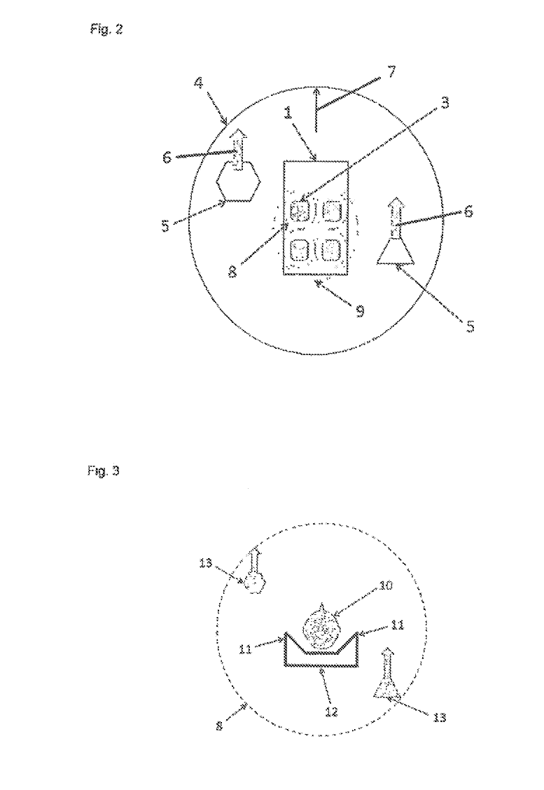

FIG. 2 shows a schematic presentation of data communication outside the vehicle 1. The circle around the vehicle 1 shows the range of the sensors 4. Within the range of the sensors 4, there are two actual dynamic objects 5 in the area, whose type, position, speed, and direction are determined (clarified in FIG. 2 by arrow 6). Another arrow 7 illustrates the direction of the vehicle 1.

In the application of the headrest installation, a personal audio area for information 8 and/or warnings (or virtual MMI sounds) are set up around the driver's seat 3. In this personal audio area 8, only information and/or warnings are emitted that are directed to a particular vehicle occupant, for example the driver, who is sitting on the seat 3 in the personal audio area 8.

Alternatively, the object based sounds (or items of information) that are created by wave field synthesis are made available in the vehicle interior to all occupants of the vehicle.

Information and/or warnings (or virtual MMI sounds) that are directed to all vehicle occupants are transmitted within an audio area 9 of the interior.

The device for creating location dependent audio data can thereby transmit information and/or warnings directly to a vehicle occupant or to all vehicle occupants, depending on which audio area it is directed to (personal audio area 8 or interior audio area 9).

In FIG. 3, a user 10, for example the driver, is presented in the personal area 8. Virtual dynamic objects 13 are emitted over a loudspeaker 11 to the driver's headrest 12, which supply to the user 10 object based (object dependent) sounds (tones) of the objects 5 with information about the type, speed, and direction of the object 5. The audio emission thereby occurs for example binaurally.

In FIG. 4 a schematic presentation of the vehicle 1 is shown.

A plurality of loudspeakers 11 are set up in the vehicle 1 for emission of virtual dynamic objects 13 and thereby of data regarding the type, speed, and direction of objects 5 communicated by sensors 2 outside the vehicle 1. The virtual dynamic objects 13 are thereby for example created by wave field synthesis (WFS).

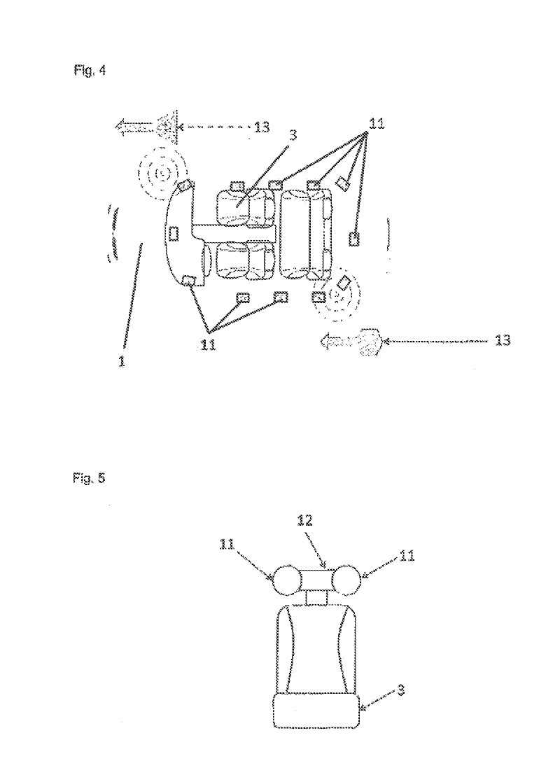

In FIG. 5, a seat 3 is shown with an audio headrest, in which a loudspeaker 11 is integrated into the address 12.

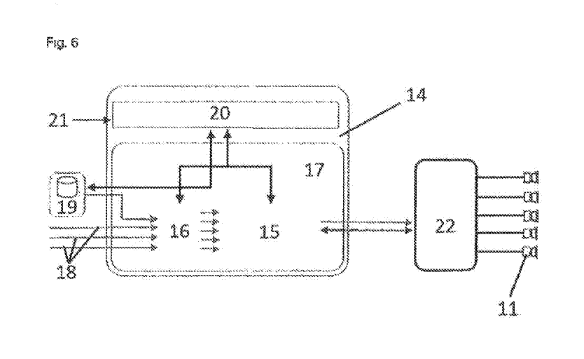

In FIG. 6 there is a schematic presentation of a device to create object dependent audio data. The MMI system 14 includes an object based audio manager 17, in which an effect device and an equalizer 16 (Audio FX) and an audio object control module 15 are set up, and where the sounds are placed and given parameters, whereby the effect device and the equalizer 16 receive audio data from a plurality of audio sources 18 and at least one (audio) database 19. In addition, the object based audio manager 17 receives metadata from an OBA control module 20 (object based audio—OBA), which is connected with an MMI server and an ADAS access module (Advanced Driver Assistance System), whereby the ADAS data 21 transmitted by the sensors 2 to the ADAS access module are transmitted.

The OBA control module 20 exchanges (meta) data with the database 19, the effect device/equalizer 16, and the audio object control module 15, or with the object based audio generator 17.

The object based audio manager 17 delivers digital audio data to a renderer 22, which controls a plurality of loudspeakers 11 and exchanges (meta) data with the object based audio manager 17. Within the renderer 22, data enter via the parameter of the construct of the loudspeaker 11 and the architecture of the space (or of the vehicle interior).

Every object 5 detected by the sensors of the vehicle 1 can be presented by using an object based audio technology as a spatial sound object.

Signals and metadata serve as initial signals, which are emitted as reproduced audio signals of the virtual sound source.

What is claimed:

1. A device to create object dependent audio data via a plurality of loudspeakers, comprising:
a database configured to store audio data;
a microprocessor configured to:
receive sensed data from a plurality of driver assistance system sensors,
retrieve corresponding data associated with the sensed data from the database,
generate sound data from the retrieved data, and
render the sound data via the plurality of loudspeakers.

2. The device according to claim 1, further comprising an equalizer, wherein the sound data is communicated to the equalizer prior to rendering.

3. The device according to claim 1, wherein the driver assistance system sensors are defined as at least one of the following: vehicle-vehicle communication systems, vehicle-infrastructure communication systems, distance sensors, microphones, communication systems, position determination systems, location determination systems, camera systems, ultrasound systems, laser navigation systems, radar systems, and navigation systems.

4. The device according to claim 1, wherein the driver assistance system sensors are embedded in a vehicle.

5. The device according to claim 1, wherein the plurality of loudspeakers are embedded in the interior of a vehicle.

6. The device according to claim 1, wherein the sound data is based on wave field synthesis.

7. The device according to claim 1, wherein the plurality of loundspeakers are defined as headrest.

8. The device according to claim 1, wherein the sound data is defined as binaurally created sound.

9. The method for creating an object dependent audio data in a vehicle interior, comprising:
receiving information from driver assistance systems;
associating a location associated with the information; and
creating sound-based data based on the associated location the received information.

10. The method according to claim 9, wherein the sound-based data undergoes a transformation via an equalizer.

11. The method according to claim 9, wherein the information includes position data of the vehicle relative to another vehicle, navigation data, information about traffic signs, traffic warning signals, local services, trace information, services connected with the vehicle, vehicle information, service information, distance data to other movable or stationary objects, information about other vehicles within a selected group of vehicles, and verbal information from the drivers within the selected group of vehicles.

12. The method according to claim 9, employing wave field synthesis to output the sound-data.
